(19) United States
(12) Patent Application Publication
(10) Pub. No.: US 2011/0124182 A1
(43) Pub. Date: May 26, 2011

(54) SYSTEM FOR THE DELIVERY OF GERMANIUM-BASED PRECURSOR

(75) Inventor: Jun-Fei Zheng, Westport, CT (US)

(73) Assignee: Advanced Techology Materials, Inc., Danbury, CT (US)

(21) Appl. No.: 12/952,183

(22) Filed: Nov. 22, 2010

Related U.S. Application Data
(60) Provisional application No. 61/263,052, filed on Nov. 20, 2009.

(51) Int. Cl. H01L 21/20; C23C 16/00

(52) U.S. Cl. 438/478; 118/726; 257/E21.09

(57) ABSTRACT

A supply of a germanium precursor such as germanium n-butylamidinate is provided in close proximity to a microelectronic device substrate to be contacted therewith for deposition of germanium-containing material on the substrate. Specific arrangements are described, including tray and reservoir structures from which solid, liquid, suspended or dissolved germanium precursor can be volatilized for transport to the substrate surface together with other precursors, carrier gases, co-reactants or the like. In such manner, the germanium precursor can be activated independently of the activation of other precursors, within the deposition chamber, to achieve highly efficient formation of germanium-containing material on the substrate, e.g., a GST film of a phase change memory device.

### CROSS-REFERENCE TO RELATED APPLICATION

The benefit of priority of U.S. Provisional Patent Application No. 61/263,052 filed Nov. 20, 2009 in the name of Jun-Fei Zheng for “SYSTEM FOR THE DELIVERY OF GERMANIUM-BASED PRECURSOR” is hereby claimed under the provisions of 35 USC 119(e). The disclosure of U.S. Provisional Patent Application No. 61/263,052 is hereby incorporated herein by reference in its entirety, for all purposes.

### TECHNICAL FIELD

The present disclosure is directed to a system for the delivery of germanium from germanium-based precursors to wafers for use in semiconductor applications.

### BACKGROUND

In prior art systems employing low vapor pressure germanium-based precursors such as germanium n-butylamidinate for the delivery of germanium to target wafers, there is oftentimes an insufficient delivery of germanium to the target wafers. This is typically due to the difficulty of maintaining sufficient vapor flux in batch processing of the wafers. One reason for this difficulty in maintaining sufficient vapor flux is that the flux is often consumed prior to coming into contact with the target wafers or specific target portions of the wafers during the process, thereby resulting in non-uniform deposition.

Additionally, the germanium is often delivered to the wafer surface using a chemical vapor deposition (CVD) process in the batch process. In using CVD to deposit the germanium in a batch process, the germanium from the precursor may be deposited in undesirable locations in the process chamber. For example, particles of the deposited germanium may clog a shower head or other device through which the precursors are introduced into the chamber, thereby bringing about the need for frequent maintenance of the chamber.

### SUMMARY

The systems described herein provide for an efficient and substantially uniform delivery of germanium from a germanium-based precursor to a plurality of target wafers in a process chamber via a CVD process. The germanium is deposited to the device sides of each of the wafers, thereby allowing the flux to be sufficiently consumed in the desired deposition process before errant particles are deposited elsewhere in the process chamber. The system also is applicable to a single wafer process.

In one aspect, the present disclosure relates to a system for the delivery of germanium n-butylamidinate precursor flux to a wafer in a batch process. This system comprises a process chamber or furnace and at least one inlet port through which germanium n-butylamidinate precursor can be delivered to an interior portion of the furnace. During delivery, the germanium n-butylamidinate is vaporized in the interior portion of the furnace. Also, in the batch process, each wafer is positioned adjacent to an internal reservoir of germanium n-butylamidinate precursor in a tray that delivers the identical and uniform flux of germanium n-butylamidinate vapor toward the wafer to achieve uniform germanium deposition. Many trays or a large tray with surface area equal to or larger than that of the total wafer surface on which devices are to be mounted will allow sufficient flux of germanium n-butylamidinate vapor.

In another aspect, the present disclosure relates to a chemical vapor deposition system for the delivery of germanium n-butylamidinate precursor to a wafer, the system comprising:

at least one tray for retaining liquid germanium n-butylamidinate precursor, the tray being heatable inside a deposition chamber of the system at a temperature above the melting point of germanium n-butylamidinate suitable to provide germanium n-butylamidinate precursor vapor, the tray comprising a plurality of tubes extending from a bottom surface of the tray and being in communication with holes uniformly distributed in the trays such that the holes allow other precursors and co-reactants to pass through;

wherein said at least one tray is arranged inside the deposition chamber such that a device side of a wafer faces the tray in parallel relationship; and wherein all the wafers when in a batch process carried out in said system will face respective trays containing germanium n-butylamidinate in a corresponding fashion so that the device side of each wafer will receive substantially uniform doses of germanium n-butylamidinate precursor flux.

In another aspect, the disclosure relates to a method of depositing germanium on a substrate in a vapor deposition chamber, comprising providing germanium n-butylamidinate in a receptacle in said vapor deposition chamber, heating the germanium n-butylamidinate in said receptacle to volatilize same to form germanium n-butylamidinate vapor, and flowing said germanium n-butylamidinate vapor to said substrate for contacting therewith.

Other aspects and features of the invention will be more fully apparent from the ensuing description and appended claims.

### BRIEF DESCRIPTION OF THE DRAWINGS

FIG. 1 is a schematic representation of a chemical vapor deposition apparatus in which germanium n-butylamidinate is stored in the chemical vapor deposition chamber and vaporized in the chamber for contacting with a semiconductor substrate.

FIG. 2 is a schematic perspective view of a tray structure for holding germanium n-butylamidinate for vaporization in a vapor deposition chamber.

FIG. 3 is a photographic perspective view of the tray structure of FIG. 2.

FIG. 4 is a top plan view of a batch process arrangement in which multiple wafers are mounted in a spaced array, above a foraminous tray holding germanium n-butylamidinate in receptacle portions of the tray, while allowing passage of vapor of other precursors as well as other fluid co-reactants or carrier gases to flow through openings of the tray.

FIG. 5 is an elevation view of the central wafer and associated tray structure of FIG. 4, taken along line A-A of FIG. 4.

FIG. 6 is a perspective schematic view of a vapor deposition chamber in which multiple wafers are mounted above respective trays that are coextensive in areal extent with the wafers.

FIG. 7 is a schematic elevation view of the multiple wafer and tray structure shown in

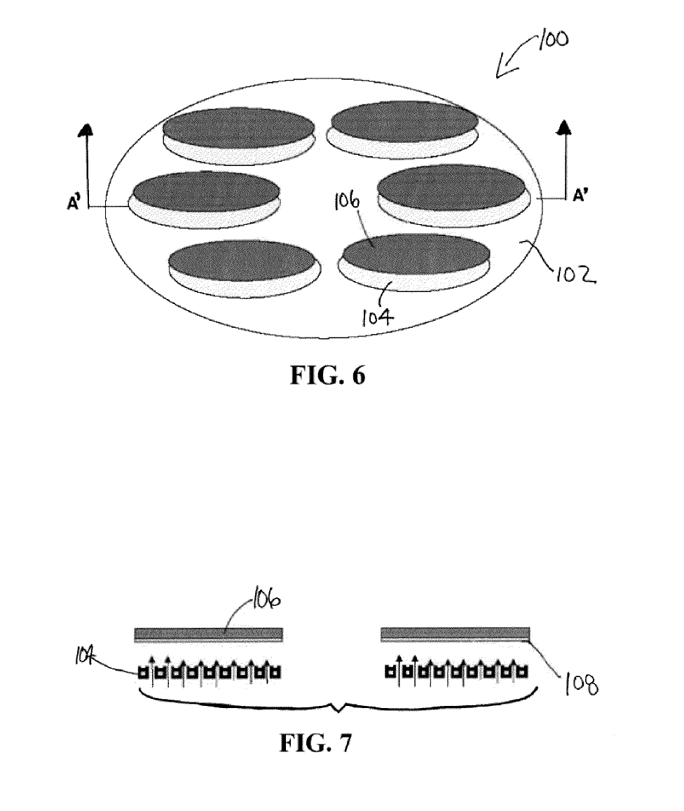

FIG. 6, taken along line A′-A′ of FIG. 6.

FIG. 8 is a schematic elevation view of a tube furnace containing multiple wafers, each mounted above a tray containing openings for flow of fluid therethrough, and receptacle portions adapted to hold germanium precursor for volatilization in the furnace to generate precursor vapor for contacting with the wafer surface.

FIG. 9 is a schematic elevation view of a microelectronic device substrate mounted below a tray including receptacle portions for holding germanium precursor and openings for allowing downflow of antimony and tellurium precursor vapors, arranged so that the germanium precursor vapor produced by volatilization of the germanium precursor in the heated chamber, is co-flowed with the antimony and tellurium precursor vapors for contacting the microelectronic device substrate.

### DETAILED DESCRIPTION

Germanium n-butylamidinate has a low vapor pressure that makes it difficult to deliver to a substrate wafer using a delivery system such as a chemical vapor deposition (CVD) system. In the delivery system of the present disclosure using a source comprising germanium butylamidinate, diterbutyltelluride, and tris(dimethylamido)antimony, the deposition of Ge, GeTe, or GeSbTe is typically at very low rate such that a film formed on the substrate wafer is desirably and suitably conformal and amorphous.

The germanium n-butylamidinate compound is preferably a compound of the formula

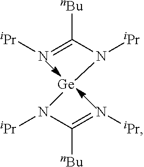

i.e., [{nBuC(iPrN)₂}₂Ge], or bis(2-butyl-N,N′-diisopropylamidinato)germanium, and is also referred to herein as GeM. The system and method of the disclosure are also applicable to other germanium amidinate compounds, of the general formula

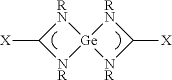

wherein:
each R is independently selected from among H, C₁-C₆ alkyl, C₅-C₁₀ cycloalkyl, C₆-C₁₀ aryl, and) —Si(R⁰)₃ wherein each R⁰ is independently selected from C₁-C₆ alkyl; and each X is independently selected from among C₁-C₆ alkyl, C₁-C₆ alkoxy, —NR¹R², and —C(R³)₃, wherein each of R¹, R² and R³ is independently selected from H, C₁-C₆ alkyl, C₅-C₁₀ cycloalkyl, C₆-C₁₀ aryl, and —Si(R⁴)₃ wherein each R⁴ is independently selected from C₁-C₆ alkyl.

A batch process in which multiple wafers are treated simultaneously is desired for efficient wafer throughput. In such a batch process, wafers may be (1) stacked side-by-side on a platform or stage, or (2) stacked with suitable spacing in a tube furnace. In either configuration, sufficient delivery of the low vapor pressure germanium n-butylamidinate precursor to the individual wafer surface while maintaining a uniform flux over the wafer surface is desired.

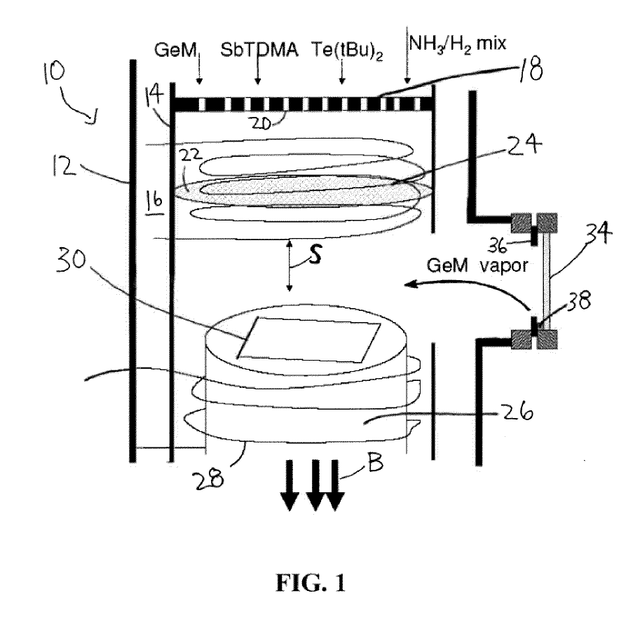

FIG. 1 is a schematic representation of a chemical vapor deposition apparatus 10 in which germanium n-butylamidinate 38 is stored in the chemical vapor deposition chamber and vaporized in the chamber for contacting with a semiconductor substrate. As shown, the chemical vapor deposition apparatus 10 includes a chamber wall 12, within which is provided a circumscribing heating shield 14, which may be formed of sheet-metal or other thermally conductive material. The chamber wall 12 and heating shield 14 thus, our coaxially arranged with respect to one another, and form an annular volume 16 therebetween.

At the upper end of the heating shield 14 is mounted a showerhead plate member 18, having openings 20 therein for downward flow through the plate member of various fluid species, including (i) the germanium precursor, bis(2-butyl-N,N-diisopropylamidinato)germanium, designated GeM, (ii) the antimony precursor, tetrakis(dimethylamido)antimony, designated SbTDMA, (iii) the tellurium precursor, di-t-butyl-tellurium, Te(tBu)₂, and (iv) the co-flow gas mixture of ammonia and hydrogen, NH₃/H₂. By such arrangement, the precursor vapors and co-reactants are flowed downwardly through the showerhead plate member. Located below such showerhead plate member is a conductive metal mesh member 22, arranged to be heated by the coil heater 24 to suitable temperature, such as a temperature in a range of from 180 to 400° C.

Positioned at a lower portion of the CVD chamber is a stage 26, arranged with a heating coil 28 so that the stage is heated to suitable temperature, e.g., temperature in a range of from 110 to 250° C., for corresponding heating of the wafer 30 mounted on the stage. The wafer may for example have a size of 2.5 cm×2.5 cm, and the spacing S between the wafer and the heating coil 24/conductive metal mesh member 22 may be on the order of 1.2 to 2.5 cm. The CVD chamber includes an observation port in the form of a laterally projecting extension 32 closed at its outer end by an observation window 34 suitably sealed to the extension by means of a coupling including gasket 36.

Between the gasket 36 and the window 34, condensed germanium precursor may be trapped as a deposit 38. When this deposit is heated, as for example to it, temperature on the order of 70° C., the precursor is re-volatilized, and resulting GeM vapor flows to the wafer 30 and is contacted therewith, to deposit germanium on such substrate.

FIG. 1 provides a schematic illustration of one exemplary embodiment of a process with internal germanium n-butylamidinate precursor delivery. The germanium n-butylamidinate precursor is heated to 130° C. in a stainless steel vessel and vaporized. For such purpose, a vaporizer vessel of a type that is commercially available from ATMI, Inc. (Danbury, Conn., USA) under the trademark ProE-Vap® can be advantageously used. Upon delivery to a CVD chamber, the vaporized precursor condenses in a cold spot at about 70° C. to form the condensate 38, which is at the window 34 of the chemical vapor deposition apparatus 10, and is stored in the CVD chamber. The condensed and stored germanium n-butylamidinate precursor is then heated to a higher temperature around 100° C., thereby causing it to vaporize and flowed to the substrate, as previously described.

By such arrangement, the precursor vapor, and co-reactants flowed downwardly through the chamber and are discharged at a lower end thereof in the direction indicated by arrows B, by action of a pump or other motive fluid driver (not shown), to remove reacted, partially reacted, and unreacted precursors and co-reactants from the chamber.

Table 1 below lists some experimental results of GeₓSb_{y}Te_{z} deposition from the precursor source materials described above, in a CVD chamber of the type described above and shown in FIG. 1, with the germanium n-butylamidinate precursor heated to about 100° C. as indicated above. The Te(tBu)₂ and SbTDMA were heated separately to increase the activation of these two precursors.

TABLE 1
Deposition Results with the Internal GeM Source from the GeM
Near the window and possibly other places inside the chamber

| Run | Ge % | Sb % | Te % | Thickness (A) | Detailed Experimental Conditions |
|---|---|---|---|---|---|
| #3031 | 24.7 | 22.3 | 53.0 | 101.8 | Substrate 150 C., precursor activation |
| | | | | | heating coil at 0.5″ above the substrate at |
| | | | | | 220 C. |
| 3032 | 29.6 | 11.2 | 59.2 | 67 | Substrate 150 C., precursor activation zone |
| | | | | | heating coil is 220 C. |
| 3033 | 35.0 | 9.25 | 55.8 | 42.7 | Substrate 130 C., precursor activation |
| | | | | | heating coil is 220 C. |
| 3034 | 30.1 | 28.5 | 41.4 | 56.6 | Substrate 125 C., precursor activation |
| | | | | | heating coil is at 186 degree C. |
| 3035 | 18.0 | 31.7 | 50.3 | 79.7 | Substrate 200 C., precursor activation |
| | | | | | heating coil is at 200 degree C. |
| 3036 | 30.1 | 28.0 | 41.9 | 58.8 | Substrate 110 C., precursor activation |
| | | | | | heating coil is at 186 degree C. |

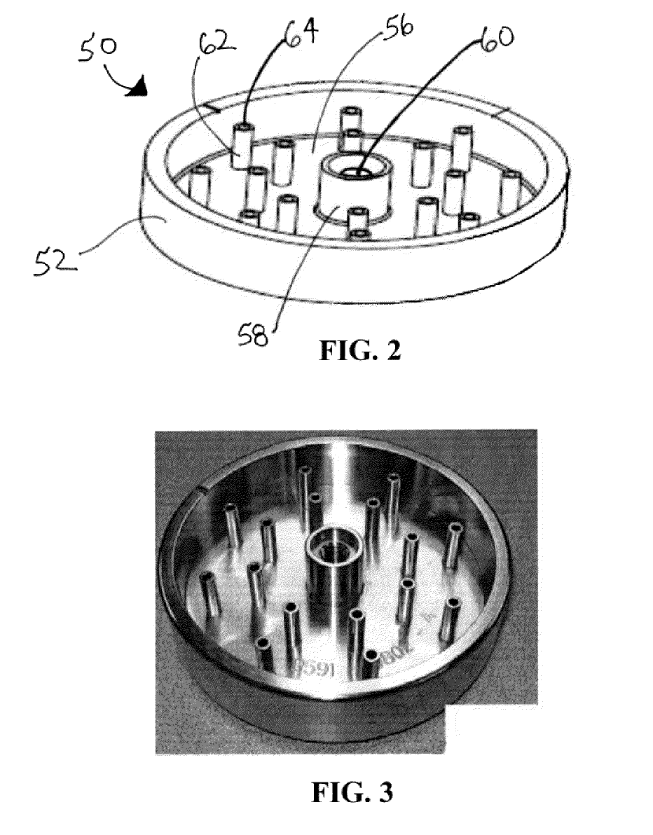

FIG. 2 is a schematic perspective view of a tray structure 50 for holding germanium n-butylamidinate for vaporization in a vapor deposition chamber. FIG. 3 is a photographic perspective view of the tray structure of FIG. 2.

As shown in FIG. 2, a configuration of a delivery system of the present disclosure for use in a CVD process is shown. In this configuration, germanium n-butylamidinate precursor is introduced into a tray of the type shown in FIG. 2. This tray includes a circumscribing sidewall 52 joined at its lower end to a bottom surface of floor member 56 having holes therein. Tubes 62 extend from the holes in the tray and define passages 64 to allow other precursors and co-reactants to pass from one side of the tray to the other. In the center of the floor member is a collar 58. Defining a central passage 60 through which one or more fluid components can be passed downwardly for subsequent upflow through the passages 64 of the tubes 62.

Germanium n-butylamidinate precursor is charged into the tray 50 in solid or liquid form or as a solid dissolved in solvent. The germanium n-butylamidinate precursor in liquid form will be at a temperature higher than 40° C. If the germanium n-butylamidinate precursor is charged into the tray in solvent, the solvent will be boiled off, thereby causing the germanium n-butylamidinate in liquid form to stay in the tray. The germanium n-butylamidinate precursor can be recharged to tray(s) of such type by injection of germanium n-butylamidinate melted at greater than the melting point, i.e., in a liquid form, or germanium n-butylamidinate can be introduced as dissolved in solvent, via a tube from a source external to the process chamber or tube furnace. As an internal germanium n-butylamidinate source, the solvent is boiled off after a charge of the germanium n-butylamidinate precursor in a solvent medium.

Thus, the tray structure shown in FIGS. 2 and 3 employs tubes 62 that allow gas/vapor to pass through, while the floor member and circumscribing sidewall of the tray cooperate to retain the germanium precursor in liquid or solid form. A tray of such type may be relatively small in size, e.g., about 10 cm in diameter, or alternatively, the tray may be constructed with a very large size, to enable the tray to be placed under many wafers mounted in side-by-side relationship to one another in a batch chemical vapor deposition chamber. Alternatively, a tray of appropriate size, e.g., 30 cm diameter, may be placed under each individual wafer in the CVD chamber, with the wafer being of a same or alternatively a different size than the tray.

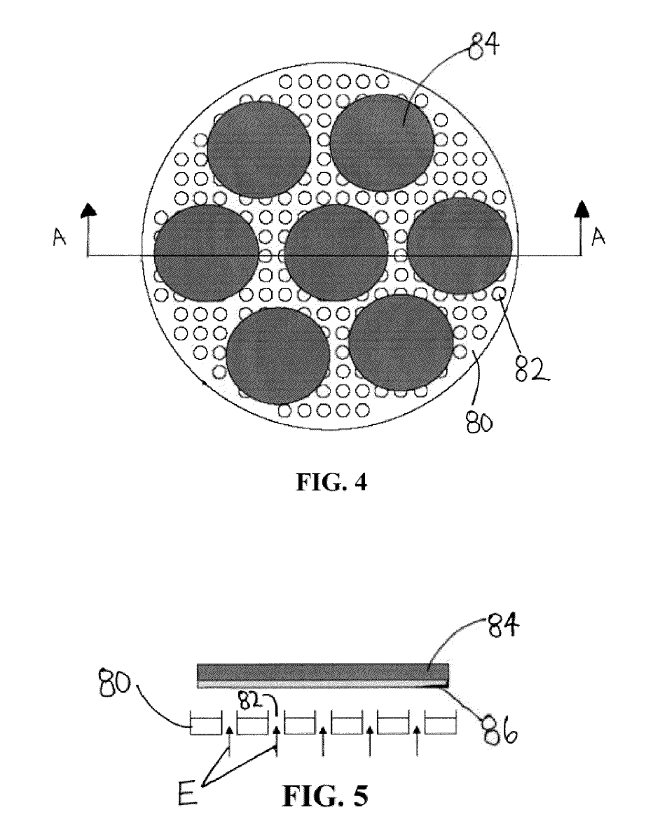

FIG. 4 is a top plan view of a batch process arrangement in which multiple wafers 84 are mounted in a spaced array, above a foraminous tray 80 holding germanium n-butylamidinate in receptacle portions of the tray, while allowing passage of vapor of other precursors as well as other fluid co-reactants or carrier gases, e.g., Te(tBu)₂, SbTDMA, carrier gas, co-reactants, etc., to flow through openings 82 of the tray. Such other precursors may be heated to a suitable temperature, e.g., in a range of from 180 to 400° C., for pre-activation thereof.

In this arrangement, the single tray 80 is mounted beneath multiple wafers in the array. The receptacle portions of the tray 80 contain germanium n-butylamidinate, which is heated to a temperature in a range of from 40 to 150° C. to volatilize the germanium precursor and form a germanium precursor vapor. Thus, the holes 82 in the tray 80 permit precursors, other than germanium n-butylamidinate, along with carrier gases, co-reactants, etc., to flow through the tray openings, while the germanium precursor is stored, with the tray functioning as a pan in which the germanium precursor is retained, and to which additional germanium precursor can be added by injection or in other suitable manner.

For example, the germanium precursor can be added in a solution or suspension, in a suitable solvent, so that subsequent to introduction to the tray, the solvent will evaporate upon heating and/or pump-down to vacuum level in the vapor deposition chamber, leaving the germanium precursor in the pan structure of the tray, so that the germanium precursor can thereafter be volatilized to form precursor vapor for contacting with the microelectronic device substrate.

FIG. 5 is an elevation view of the central wafer 84 and associated tray structure 80 of FIG. 4, taken along line A-A of FIG. 4. As illustrated in FIG. 4, many wafers can be arranged to have their device surface (the surfaces of the wafers on which devices are located) facing the direction of germanium n-butylamidinate vapor flux from the tray. The Sb, Te, and any co-reactants involved will pass through the openings in the tray, schematically represented as holes 82. The germanium precursor retained in the receptacle portion of the tray between the tube openings will then volatilize and form a vapor flux that contacts the device side 86 of the microelectronic device substrate, so that the germanium precursor vapor co-flows with the other precursors being flowed in the direction indicated by arrows E toward the substrate.

FIG. 6 is a perspective schematic view of a vapor deposition chamber 100 defining an interior chamber volume 102 in which multiple wafers 106 are mounted above respective trays 104 that are coextensive in areal extent with the respective wafers with which they are associated. Thus, in this arrangement, there are as many trays as wafers, with the size of the trays being the same as the size of the wafers in diameter and area, and both being circular or disk-like in shape.

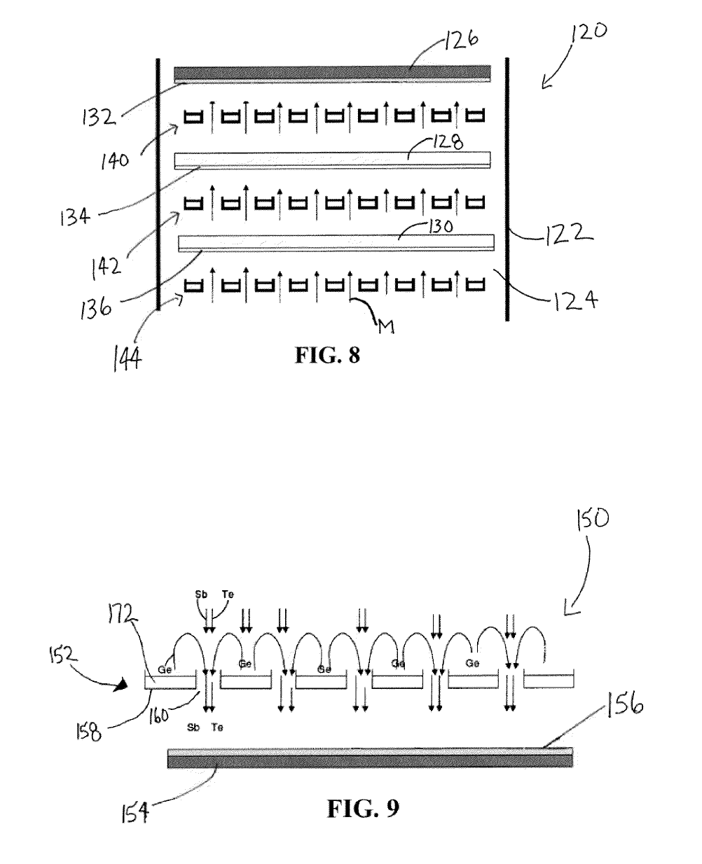

FIG. 7 is a schematic elevation view of the multiple wafer and tray structure shown in FIG. 6, taken along line A′-A′ of FIG. 6. As illustrated, the microelectronic device substrate, wafer 106, is oriented with its device side 108 facing the tray 104. In this manner, the germanium precursor held in the receptacle portion of the tray is volatilized and flows with the precursor vapor of other precursors (passing through openings of the tray, in the direction indicated by arrows) for contacting with the device side 108 of the substrate 106.

The delivery of the germanium n-butylamidinate precursor from a tray is a proportional function of the inner surface area of that tray. By using the tray specified in FIGS. 2, 3, 6, and 7, the inner surface area of the trays is as large as that of the wafer surface, which will lead to sufficient delivery of GeM to the wafer. Also, the wafers are positioned such that the device side of each faces the tray, with the surfaces of the device sides parallel to the trays containing germanium n-butylamidinate. A plurality of trays may be alternatingly stacked with the wafers such that precursor flux is in the direction of the device side of each wafer, to enable substantially uniform delivery of germanium n-butylamidinate precursor flux to the device side of each wafer.

FIG. 8 is a schematic elevation view of a tube furnace 120 including a furnace housing 122 defining an enclosed interior volume 124 containing multiple wafers 126, 128 and 130, each mounted above a tray 140, 142 and 144, respectively, with the trays containing openings for flow of fluid therethrough in the direction indicated by arrows M. The trays also include receptacle portions adapted to hold germanium precursor for volatilization in the furnace to generate precursor vapor for contacting with the wafer surface. In this orientation, the wafers are arranged with their device sides 132, 134 and 136 in facing relationship to the tray retaining the germanium precursor, and generating a germanium precursor vapor flux for contacting with the device side of the corresponding wafer.

In the FIG. 8 arrangement, wafers are stacked vertically inside a tube furnace with the device side facing the vaporization of the precursors in the tray. There are as many trays as there are wafers, with each tray under a corresponding wafer. The tray can be loaded into the tube furnace in a similar fashion as the wafer, after the tray is loaded with precursor for each run.

In the configurations shown in FIGS. 4-8, the trays can be stationed inside the deposition chamber under continuous vacuum without the interference of loading and unloading the wafers via a vacuum load lock. In the configurations in FIGS. 6-8, however, the trays can be removed from the chamber or the tube furnace and put back as desired in a similar fashion of taking wafers in and out using a robotic transfer mechanism, provided such transfers keep the trays containing germanium n-butylamidinate under vacuum. The configurations in FIGS. 6-8 allow for the easy maintenance of the trays, such as cleaning the trays.

Although FIGS. 4-8 show that the device sides of the wafers are facing down to receive the germanium n-butylamidinate from the trays and Sb and Te precursors flowing upwardly through the holes of the trays, the wafers can also be placed with the device sides facing upward and with the trays containing germanium n-butylamidinate above the wafer. In this case, the vaporized germinanium n-butylamidinate will pass toward the wafer device side surfaces through the holes, together with the Sb and Te precursor. This is shown in FIG. 9.

FIG. 9 is a schematic elevation view of a vapor deposition chamber arrangement 150 including a microelectronic device substrate 154 oriented with its device side 156 on top, and mounted below a tray 152 including receptacle portions 158 for holding germanium precursor 172 and openings 160 for allowing downflow of antimony and tellurium precursor vapors in the direction indicated by corresponding arrows. By this arrangement, the germanium precursor vapor produced by volatilization of the germianium precursor in the heated chamber is co-flowed with the antimony and tellurium precursor vapors for contacting the device side 156 of the microelectronic device substrate 154.

In operation, the vaporized germanium n-butylamidinate precursor is carried toward the device side of the wafer surface via holes 160 after vaporizing and leaving the surface of the tray 152. Other precursors such as Te(tBu)₂ and SbTDMA, carrier gas, co-reactants, etc. pass through the holes. One or more of the precursors can be heated by a hot zone, e.g., to temperature in a range of from 180° C. to 400° C., in the precursor passage during its flow toward the wafer device side surface 156, for pre-activation of such precursors.

Although this disclosure has been set forth and described with respect to the detailed embodiments thereof, it will be understood by those of skill in the art that various changes may be made and equivalents may be substituted for elements thereof without departing from the scope of the disclosure. In addition, modifications may be made to adapt a particular situation or material to the teachings of the disclosure without departing from the essential scope thereof. Therefore, it is intended that the disclosure not be limited to the particular embodiments disclosed in the above detailed description, but that the disclosure will include all embodiments falling within the scope of the foregoing description, the drawings, and the appended claims hereof.

What is claimed is:

1. A chemical vapor deposition system for the delivery of germanium n-butylamidinate precursor to a wafer, the system comprising:
at least one tray for retaining liquid germanium n-butylamidinate precursor, the tray being heatable inside a deposition chamber of the system at a temperature above the melting point of germanium n-butylamidinate suitable to provide germanium n-butylamidinate precursor vapor, the tray comprising a plurality of tubes extending from a bottom surface of the tray and being in communication with holes uniformly distributed in the trays such that the holes allow other precursors and co-reactants to pass through;
wherein said at least one tray is arranged inside the deposition chamber such that a device side of a wafer faces the tray in parallel relationship; and
wherein all the wafers when in a batch process carried out in said system will face respective trays containing germanium n-butylamidinate in a corresponding fashion so that the device side of each wafer will receive substantially uniform doses of germanium n-butylamidinate precursor flux.

2. The chemical vapor deposition system of claim 1, wherein the tray containing germanium n-butylamidinate precursor contains a plurality of wafers located thereon arranged side-by-side and the device side of each wafer faces the vapor of germanium n-butylamidinate from the tray when the tray is heated to temperature in a range of from 40° C. to 150° C.

3. The chemical vapor deposition system of claim 1, comprising a plurality of trays, each tray corresponding substantially to the size of a respective wafer, in a side-by-side tray arrangement.

4. The chemical vapor deposition system of claim 1, wherein a plurality of wafers and trays are alternatingly stacked in the deposition chamber of a tube furnace, with the device side of each wafer facing an adjacent tray.

5. The chemical vapor deposition system of claim 3, wherein each tray can be transferred out of deposition chamber for maintenance.

6. The chemical vapor deposition system of claim 1, adapted to effect a re-charge of germanium n-butylamidinate precursor to the trays by injection of germanium n-butylamidinate melted at greater than the melting point or germanium n-butylamidinate dissolved in solvent, via a tube from a source of same external to the deposition chamber.

7. A method of depositing germanium on a substrate in a vapor deposition chamber, comprising providing germanium n-butylamidinate in a receptacle in said vapor deposition chamber, heating the germanium n-butylamidinate in said receptacle to volatilize same to form germanium n-butylamidinate vapor, and flowing said germanium n-butylamidinate vapor to said substrate for contacting therewith.
